(19) United States
(12) Patent Application Publication
(10) Pub. No.: US 2005/0224902 A1
(43) Pub. Date: Oct. 13, 2005

(54) Wireless substrate-like sensor

(76) Inventors: Craig C. Ramsey, West Linn, OR (US); DelRae H. Gardner, Tualatin, OR (US); Jeffrey K. Lassahn, Portland, OR (US)

Correspondence Address: WESTMAN, CHAMPLIN & KELLY, P.A., Suite 1600 - International Centre, 900 Second Avenue South, Minneapolis, MN, 55402-3319, US

(21) Appl. No.: 11/075,363

(22) Filed: Mar. 8, 2005

Related U.S. Application Data
(63) Continuation-in-part of application No. 10/356,684, filed on Jan. 31, 2003.
(60) Provisional application No. 60/551,460, filed on Mar. 9, 2004.
(60) Provisional application No. 60/354,551, filed on Feb. 6, 2002.

(51) Int. Cl. H01L 21/338

(52) U.S. Cl. 257/433; 257/434

(57) ABSTRACT

In accordance with an aspect of the present invention, a wireless substrate-like sensor is configured to be low-profile. One exemplary low-profile design includes using an image acquisition system on a leadless ceramic carrier chip. Then a circuit board, or rigid interconnect, is provided with a recess to accommodate the image acquisition system. The image acquisition system is disposed within the recess and coupled to the board through the periphery of the leadless ceramic carrier chip.

### CROSS-REFERENCE OF CO-PENDING APPLICATIONS

The present application claims priority to previously filed co-pending provisional application Ser. No. 60/551,460, filed Mar. 9, 2004, entitled WIRELESS SUBSTRATE-LIKE SENSOR, which application is incorporated herein by reference in its entirety; and the present application is a Continuation-In-Part of U.S. patent application Ser. No. 10/356,684, filed Jan. 31, 2003, entitled WIRELESS SUBSTRATE-LIKE SENSOR.

### BACKGROUND OF THE INVENTION

Semiconductor processing systems are characterized by extremely clean environments and extremely precise semiconductor wafer movement. Industries place extensive reliance upon high-precision robotic systems to move substrates, such as semiconductor wafers, about the various processing stations within a semiconductor processing system with the requisite precision.

Reliable and efficient operation of such robotic systems depends on precise positioning, alignment, and/or parallelism of the components. Accurate wafer location minimizes the chance that a wafer may accidentally scrape against the walls of a wafer processing system. Accurate wafer location on a process pedestal in a process chamber may be required in order to optimize the yield of that process. Precise parallelism between surfaces within the semiconductor processing systems is important to ensure minimal substrate sliding or movement during transfer from a robotic end effector to wafer carrier shelves, pre-aligner vacuum chucks, load lock elevator shelves, process chamber transfer pins and/or pedestals. When a wafer slides against a support, particles may be scraped off that cause yield loss. Misplaced or misaligned components, even on the scale of fractions of a millimeter, can impact the cooperation of the various components within the semiconductor processing system, causing reduced product yield and/or quality.

This precise positioning must be achieved in initial manufacture, and must be maintained during system use. Component positioning can be altered because of normal wear, or as a result of procedures for maintenance, repair, alteration, or replacement. Accordingly, it becomes very important to automatically measure and compensate for relatively minute positional variations in the various components of a semiconductor processing system.

In the past, attempts have been made to provide substrate-like sensors in the form of a substrate, such as a wafer, which can be moved through the semiconductor processing system to wirelessly convey information such as substrate inclination and acceleration within the semiconductor system. As used herein, “substrate-like” is intended to mean a sensor in the form of substrate such as a semiconductor wafer, a Liquid Crystal Display glass panel or reticle. Attempts have been made to provide wireless substrate-like sensors that include additional types of detectors to allow the substrate-like sensor to measure a host of internal conditions within the processing environment of the semiconductor processing system. Wireless substrate-like sensors enable measurements to be made at various points throughout the processing equipment with reduced disruption of the internal environment as well as reduced disturbance of the substrate handling mechanisms and fabrication processes (e.g.: baking, etching, physical vapor deposition, chemical vapor deposition, coating, rinsing, drying etc.). For example, the wireless substrate-like sensor does not require that a vacuum chamber be vented or pumped down; nor does it pose any higher contamination risk to an ultra-clean environment than is suffered during actual processing. The wireless substrate-like sensor form factor enables measurements of process conditions with minimal observational uncertainty.

Since wireless substrate-like sensors are transported through the actual semiconductor processing environment, it is important that they not adversely affect the environment itself. Thus, such sensors should not allow particles to break off therefrom, nor outgas. Moreover, in order to ensure that such sensors can move to every location within the semiconductor processing environment that a normal substrate could move to, the dimensions of the sensor should be at least as small as a maximum substrate size, but preferably smaller. Finally, in order to ensure accuracy of measurements of the sensor, it is important that the sensor's weight does not cause any significant deflection or other form of displacement on the handling apparatus. Thus, such sensors should be relatively light-weight.

Thus, there exists a current need in the field of wireless substrate-like sensors for devices that are clean, light-weight, and low-profile.

### SUMMARY OF THE INVENTION

In accordance with an aspect of the present invention, a wireless substrate-like sensor is configured to be low-profile. One exemplary low-profile design includes using an image acquisition system on a leadless ceramic carrier chip. Then a circuit board, or rigid interconnect, is provided with a recess to accommodate the image acquisition system. The image acquisition system is disposed within the recess and coupled to the board through the periphery of the leadless ceramic carrier chip.

### BRIEF DESCRIPTION OF THE DRAWINGS

FIG. 1 is a diagrammatic view of a semiconductor wafer process environment.

FIG. 2 is a top perspective view of a wireless substrate-like sensor in accordance with embodiments of the present invention.

FIG. 3 is a bottom view of a wireless substrate-like sensor in accordance with embodiments of the present invention.

FIG. 4 is a diagrammatic view of central portion 120 in accordance with embodiments of the present invention.

FIG. 5 is a diagrammatic view of an image acquisition system disposed upon a printed circuit board.

FIG. 6 is a diagrammatic view of an image acquisition system mounted within a printed circuit board in accordance with an embodiment of the present invention.

FIG. 7 is a perspective view illustrating mounting a CLCC package within a recess in a printed circuit board in accordance with an embodiment of the present invention.

FIG. 8 is a diagrammatic view of an image acquisition system mounted to a printed circuit in accordance with an embodiment of the present invention.

FIG. 9 is a perspective view of a wireless substrate-like sensor having a vent in accordance with an embodiment of the present invention.

FIG. 10 is a cross sectional view of a wireless substrate-like sensor having a deformable pressure equalization member in accordance with an embodiment of the present invention.

### DETAILED DESCRIPTION OF THE PREFERRED EMBODIMENTS

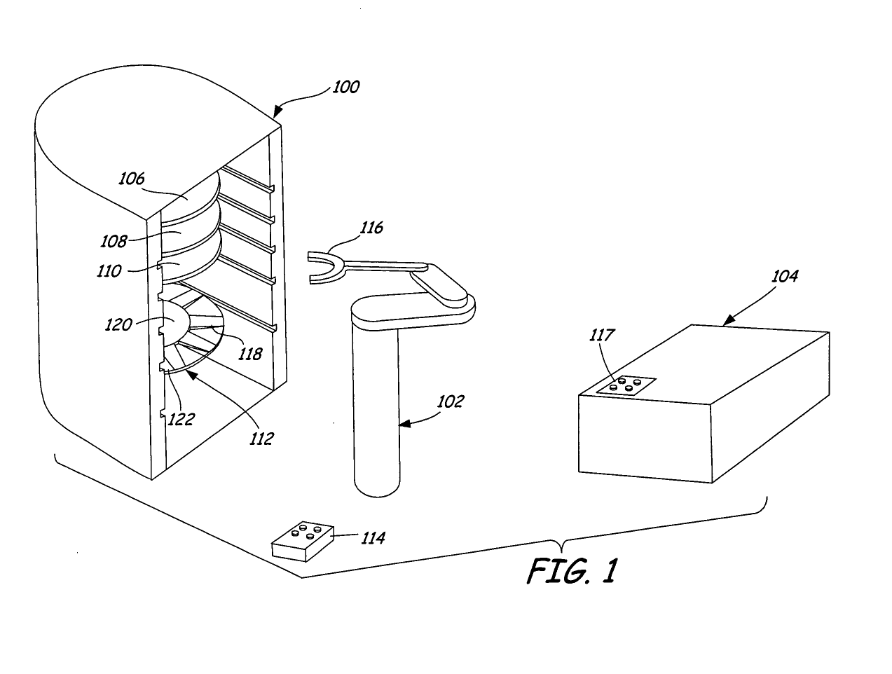

FIG. 1 is a diagrammatic view of a semiconductor wafer processing environment including a wafer container 100, robot 102 and system component station 104 illustrated diagrammatically as simply a box. Wafer container 100 is illustrated containing three wafers 106, 108, 110 and wireless substrate-like sensor 112 in accordance with embodiments of the present invention. As is apparent from FIG. 1, sensor 112 is preferably embodied in a form factor allowing it to be moveable within the semiconductor wafer processing environment in the same manner as wafers themselves. Accordingly, embodiments of the present invention provide a substrate-like wireless sensor having a height low enough to permit the substrate-like sensor to move through the system as if it were a substrate such as a wafer. For example, a height of less than about 9.0 mm is believed to be acceptable. Preferably, the sensor has a weight between 1 to 2 wafers, for example, a weight between about 125 grams and about 250 grams is believed to be acceptable. A stand-off distance of about 25 mm is believed to meet the requirements of most applications; however some applications may require a different stand-off. As used herein “stand-off” is the nominal distance from the bottom of the sensor to the target. The diameter of the sensor preferably matches one of the standard semiconductor wafer diameters, such as, 300 mm, 200 mm or 150 mm.

Sensor 112 is preferably constructed from light-weight, dimensionally stable materials. Sensor 112 is preferably constructed from a base material that has a high stiffness such as an aluminum alloy, aluminum, magnesium, and/or a ceramic. The sensor housing itself may be coated with any suitable coatings including aluminum oxide, nickel, or ceramics in order to improve mechanical or chemical properties.

In order for the substrate-like sensor to accurately measure a three-dimensional offset, it is important for the sensor to deform in a manner similar to that of an actual substrate. Common wafer dimensions and characteristics may be found in the following specification: SEMI M1-0302, “Specification for Polished Monocrystaline Silicon Wafers”, Semiconductor Equipment and Materials International, www.semi.org. The center of a 300 mm silicon wafer supported at its edges will sag approximately 0.5 mm under its own weight. The difference in the deformation of the sensor and the deformation of an actual wafer should be much less than the accuracy of sensor measurement. In a preferred embodiment, the stiffness of the substrate-like sensor results in a deflection that is nearly identical to that of an actual silicon wafer. Therefore, no compensation is required to correct for any differential deflection. Alternatively, a compensation factor may be added to the measurement. Similarly, the weight of the substrate-like sensor will also deflect its support. Substrate supports include, but are not limited to: end effectors, pedestals, transfer pins, shelves, etc. The differential support deflection will be a function both of the difference in weights of the sensor and a substrate as well as the mechanical stiffness of the substrate support. The difference between deflection of the support by the sensor and that by a substrate should also be much less than the accuracy of sensor measurement, or the deflection difference should be compensated by a suitable calculation.

In the prior art, technicians have iteratively adjusted the alignment of a vacuum transfer robot end effector with a process chamber pedestal by viewing them after removing the lid of the process chamber or through a transparent window in the lid. Sometimes a snuggly fitting fixture or jig must first be placed on the process pedestal to provide a suitable reference mark. The substrate-like sensor enables an improved, technician assisted, alignment method. The substrate-like sensor provides an image of the objects being aligned without the step of removing the cover and with greater clarity than viewing through a window. The wireless substrate-like sensor saves significant time and improves the repeatability of alignment.

A wireless substrate-like sensor can transmit an analog camera image by radio.

A preferred embodiment uses a machine vision sub-system of a substrate-like wireless sensor to transmit all or a portion of the digital image stored in its memory to an external system for display or analysis. The display may be located near the receiver or the image data may be relayed through a data network for remote display. In a preferred embodiment, the camera image is transmitted encoded as a digital data stream to minimize degradation of image quality caused by communication channel noise. The digital image may be compressed using any of the well known data reduction methods in order to minimize the required data rate. The data rate may also be significantly reduced by transmitting only those portions of the image that have changed from the previous image. The substrate-like sensor or the display may overlay an electronic cross hair or other suitable mark to assist the technician with evaluating the alignment quality.

While vision-assisted teaching is more convenient than manual methods, technician judgment still affects the repeatability and reproducibility of alignment. The image acquired by a substrate-like wireless sensor camera may be analyzed using many well-known methods, including two-dimensional normalized correlation, to measure the offset of a pattern from its expected location. The pattern may be an arbitrary portion of an image that the vision system is trained to recognize. The pattern may be recorded by the system. The pattern may be mathematically described to the system. The mathematically described pattern may be fixed at time of manufacture or programmed at the point of use. Conventional two-dimensional normalized correlation is sensitive to changes in the pattern image size. When a simple lens system is used, magnification varies in proportion to object distance. Enhanced pattern offset measurement performance may be obtained by iteratively scaling either the image or the reference. The scale that results in the best correlation indicates the magnification, provided the size of the pattern is known, or the magnification, as used when the reference pattern was recorded, is known.

When the correspondence between pixels in the image plane to the size of pixels in the object plane is known, offsets may be reported in standard units of measure that are easier for technicians or machine controllers to interpret than arbitrary units such as pixels. For example, the offset may be provided in terms of millimeters such that the operator can simply adjust the systems by the reported amount. The computations required to obtain the offset in standard units may be performed manually, by an external computer, or preferentially within the sensor itself. When the sensor extracts the required information from an image, the minimum amount of information is transmitted and the minimum computational burden is placed on the technician or external controller. In this way objective criteria may be used to improve the repeatability and reproducibility of the alignment. Automated offset measurement improves the reproducibility of alignment by removing variation due to technician judgment.

During alignment and calibration of semiconductor processing equipment, it is not only important to correctly position an end effector relative to a second substrate supporting structure, it is also important to ensure that both substrate supporting structures are parallel to one another. In a preferred embodiment, a machine vision subsystem of a wireless substrate-like sensor is used to measure the three dimensional relationship between two substrate supports. For example: a robotic end effector may hold a wireless substrate-like sensor in close proximity to the transfer position and a measurement of the three dimensional offset with six degrees of freedom may be made from the sensor camera to a pattern located on an opposing substrate support. One set of six degrees of freedom includes yaw, pitch, and roll as well as displacement along the x, y, and z axes of the Cartesian coordinate system. However, those skilled in the art will appreciate that other coordinate systems may be used without departing from the spirit and scope of the invention. Simultaneous measurement of both parallelism and Cartesian offset allows a technician or a controller to objectively determine satisfactory alignment. When a controller is used, alignments that do not require technician intervention may be fully automated. Automated alignments may be incorporated into scheduled preventive maintenance routines that optimize system performance and availability.

In a very general sense, operation and automatic calibration of robotic system 102 is performed by instructing robot 102 to select and convey sensor 112 to reference target 114. Once instructed, robot 102 suitably actuates the various links to slide end effector 116 under sensor 112 to thereby remove sensor 112 from container 100. Once removed, robot 102 moves sensor 112 directly over reference target 114 to allow an optical image acquisition system (not shown in FIG. 1) within sensor 112 to obtain an image of reference target 114. Based upon a-priori knowledge of the target pattern, a three dimensional offset between the sensor and target 114 is measured. The measurement computation may occur within the sensor or an external computer. Based upon a-priori knowledge of the precise position and orientation of reference target 114, the three dimensional offset thereof can be analyzed to determine the pick-up error generated by robot 102 picking up sensor 112. Either internal or external computation allows the system to compensate for any error introduced by the pick-up process of sensor 112.

This information allows sensor 112 to be used to acquire images of additional targets, such as target 116 on system component 104 to calculate a precise position and orientation of system component 104. Repeating this process allows the controller of robot 102 to precisely map exact positions of all components within a semiconductor processing system. This mapping preferably generates location and orientation information in at least three and preferably six degrees of freedom (x, y, z, yaw, pitch and roll). The mapping information can be used by a technician to mechanically adjust the six degree of freedom location and orientation of any component with respect to that of any other component. Accurate measurements provided by the substrate-like wireless sensor are preferably used to minimize or reduce variability due to technician judgment. Preferably, this location information is reported to a robot or system controller which automates the calibration process. After all mechanical adjustments are complete; the substrate-like sensor may be used to measure the remaining alignment error. The six degrees of freedom offset measurement may be used to adjust the coordinates of points stored in the memories of the robot and/or system controllers. Such points include, but are not limited to: the position of an atmospheric substrate handling robot when an end effector is located at a FOUP slot #1 substrate transfer point; the position of an atmospheric substrate handling robot when an end effector is located at a FOUP slot #25 substrate transfer point; the position of an atmospheric substrate handling robot when an end effector is located at a substrate pre-aligner substrate transfer point; the position of an atmospheric substrate handling robot when an end effector is located at a load lock substrate transfer point; the position of an atmospheric substrate handling robot when an end effector is located at a reference target attached to the frame of an atmospheric substrate handling system; the position of a vacuum transfer robot when its end effector is located at a load lock substrate transfer point; the position of a vacuum transfer robot when an end effector is located at a process chamber substrate transfer point; and the position of a vacuum transfer robot when an end effector is located at a target attached to the frame of a vacuum transfer system.

An alternative embodiment of the present invention stores and reports the measurements. Real-time wireless communication may be impractical in some semiconductor processing systems. The structure of the system may interfere with wireless communication. Wireless communication energy may interfere with correct operation of a substrate processing system. In these cases, sensor 112 can preferably record values as it is conveyed to various targets, for later transmission to a host. When sensor 112, using its image acquisition system, or other suitable detectors, recognizes that it is no longer moving, sensor 112 preferably records the time and the value of the offset. At a later time, when sensor 112 is returned to its holster (not shown) sensor 112 can recall the stored times and values and transmit such information to the host. Such transmission may be accomplished by electrical conduction, optical signaling, inductive coupling or any other suitable means. Store and report operation of the wireless substrate-like sensor potentially: increases the reliability, lowers the cost and shortens a regulatory approval cycle for the system. Moreover, it avoids any possibility that the RF energy could interact with sensitive equipment in the neighborhood of the sensor and its holster. Store and report operation can also be used to overcome temporary interruptions of a real-time wireless communication channel.

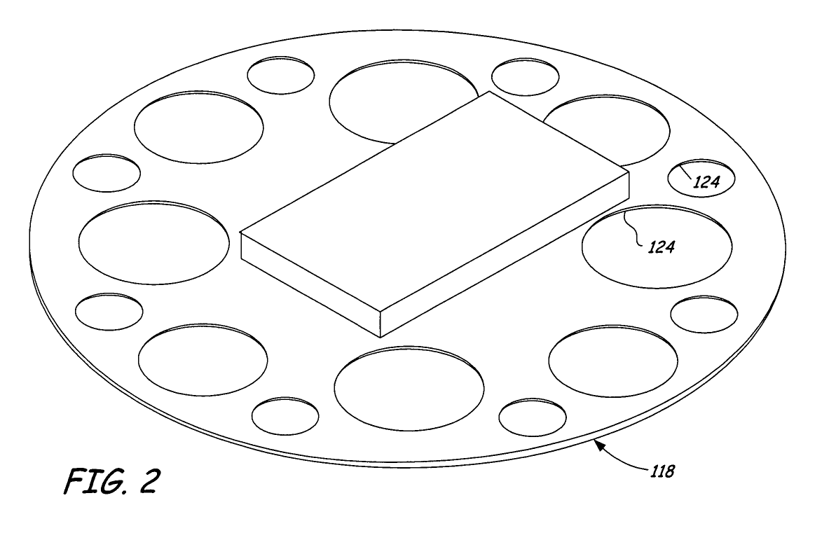

FIG. 2 is a top perspective view of a wireless substrate-like sensor 118 in accordance with embodiments of the present invention. Sensor 118 differs from sensor 112 illustrated in FIG. 1 solely in regard to the manner in which weight reduction is effected. Specifically, sensor 112 employs a number of struts 118 to suspend a central sensor portion 120 within an outer periphery 122 that can accommodate standard wafer sizes, such as 300 millimeter diameter wafers. In contrast, sensor 118 employs a number of through-holes 124 which also provide weight reduction to sensor 118. Other patterns of holes may be used to accomplish the necessary weight reduction. Further, stiffening ribs, such as those illustrated in FIG. 1, can be used alone, or in combination with lightening holes to allow the housing design to be optimized for strength, stiffness and weight. Additional weight reduction designs are also contemplated including, for example, portions of the sensor that are hollow, and/or portions that are filled with light-weight materials. Other weight reducing and stiffening features, which may be used, including circular holes, spokes, lattices honeycombs, etc. Alternatively, holes may be formed, for example, by etching into crystalline substrates such as single crystal silicon. The weight saved by removing the unneeded material allows for larger batteries providing longer periods of wireless operation, and/or additional components that provide more powerful signal conditioning, additional sensing modes and/or real-time wireless communication.

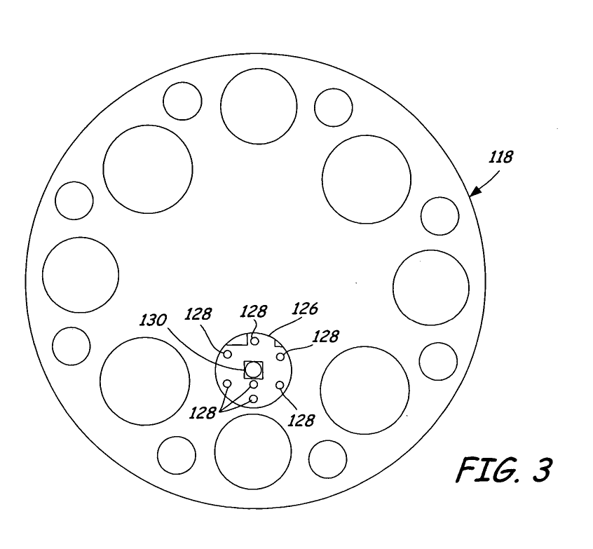

Both sensor 112 and sensor 118 employ central region 120. A portion of the underside of central portion 120 is disposed directly over an access hole 126 as illustrated in FIG. 3. Access hole 126 allows illuminator 128 and image acquisition system 130 to acquire images of targets disposed below sensor 118 as sensor 118 is moved by robot 102.

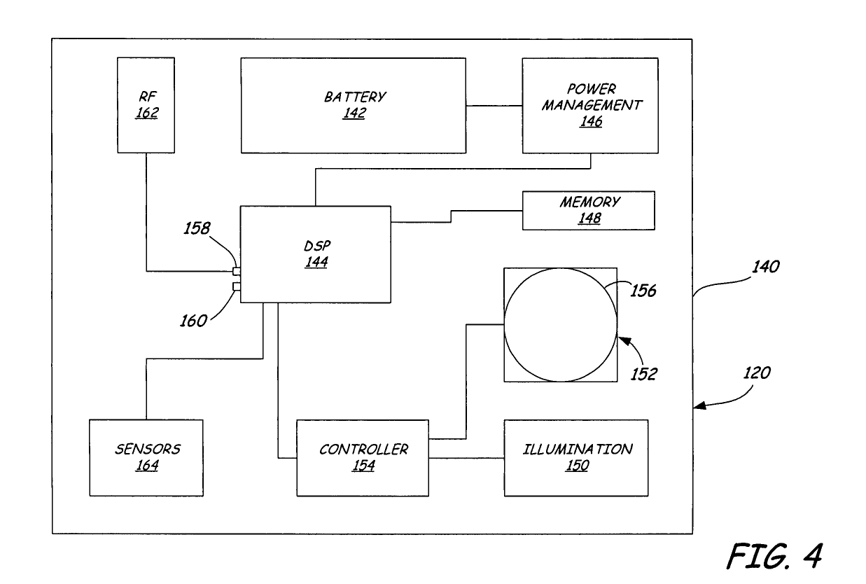

FIG. 4 is a diagrammatic view of portion 120 in accordance with embodiments of the present invention. Portion 120 preferably includes a circuit board 140 upon which a number of components are mounted. Specifically, battery 142 is preferably mounted on circuit board 140 and coupled to digital signal processor (DSP) 144 via power management module 146. Power management module 146 ensures that proper voltage levels are provided to digital signal processor 144. Preferably, power management module 146 is a power management integrated circuit available from Texas Instrument under the trade designation TPS5602. Additionally, digital signal processor 144 is preferably a microprocessor available from Texas Instruments under the trade designation TMS320C6211. Digital signal processor 144 is coupled to memory module 148, which can take the form of any type of memory. Preferably, however, memory 148 includes a module of Synchronous Dynamic Random Access Memory (SDRAM) preferably having a size of 16M×16. Module 148 also preferably includes flash memory having a size of 256K×8. Flash memory is useful for storing such non-volatile data as programs, calibration data and/or additional other non-changing data as may be required. The random access memory is useful for storing volatile data such as acquired images or data relevant to program operation.

Illumination module 150, which preferably comprises a number of Light Emitting Diodes (LEDs), and image acquisition system 152 are coupled to digital signal processor 144 through camera controller 154. Camera controller 154 facilitates image acquisition and illumination thus providing relevant signaling to the LEDs and image acquisition system 152 as instructed by digital signal processor 144. Image acquisition system 152 preferably comprises an area array device such as a Charge Coupled Device (CCD) or Complementary Metal Oxide Semiconductor (CMOS) image device coupled preferably to an optical system 156, which focuses images upon the array. Preferably, the image acquisition device is available from Kodak under the trade designation KAC-0310. Digital signal processor 144 also preferably includes a number of I/O ports 158, 160. These ports are preferably serial ports that facilitate communication between digital signal processor 144 and additional devices. Specifically, serial port 158 is coupled to radio-frequency module 162 such that data sent through port 158 is coupled with external devices via radio frequency module 162. In one preferred embodiment, radio frequency module 162 operates in accordance with the well-known Bluetooth standard, Bluetooth Core Specification Version 1.1 (Feb. 22, 2001), available from the Bluetooth SIG (www.bluetooth.com). One example of module 162 is available from Mitsumi under the trade designation WML-C11.

Detectors 164 may take any suitable form and provide relevant information regarding any additional conditions within a semiconductor processing system. Such detectors can include one or more thermometers, accelerometers, inclinometers, compasses (Magnetic field direction detectors), light detectors, pressure detectors, electric field strength detectors, magnetic field strength detectors, acidity detectors, acoustic detectors, humidity detectors, chemical moiety activity detectors, or any other types of detector as may be appropriate.

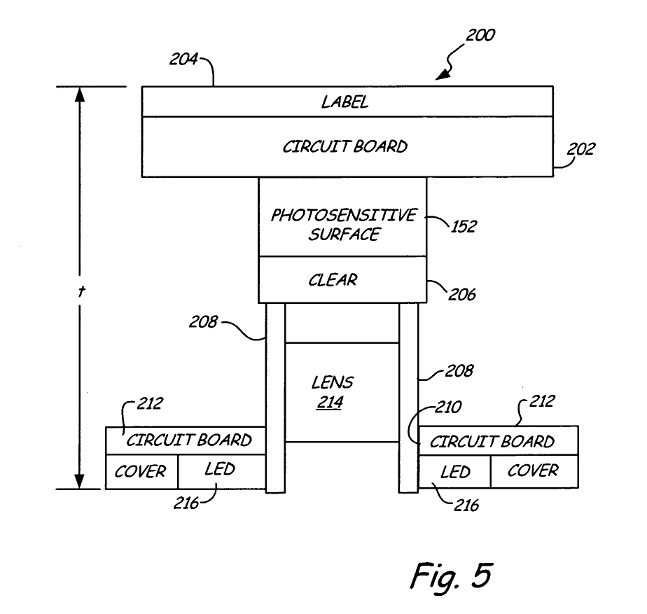

FIG. 5 is a diagrammatic view of image acquisition system 152 mounted to circuit board 202. A label 204 is generally disposed on the backside of circuit board 202. A clear coating or lens 206 is disposed proximate image acquisition device 152. Tubular passageway 208 extends through hole 210 in circuit board 212 with lens 214 disposed therein. The outer periphery of lens 214 and the inner diameter of tube 208 are preferably threaded such that rotation of lens 214 within tube 208 can be used to change image focus. One or more LEDs 216 are coupled to circuit board 212 and provide illumination for image acquisition. The configuration illustrated in FIG. 5 results in an overall thickness t that is approximately 8.5 millimeters using commercially available materials and devices. The difficulty arises in some wireless substrate-like applications where the sensor itself must passthrough a slot, or other aperture, having a thickness less than 8.5 millimeters. In accordance with one embodiment of the present invention, these same commercially available components are arranged in a low-profile configuration that reduces the profile of the overall sensor by the approximate thickness of the circuit board.

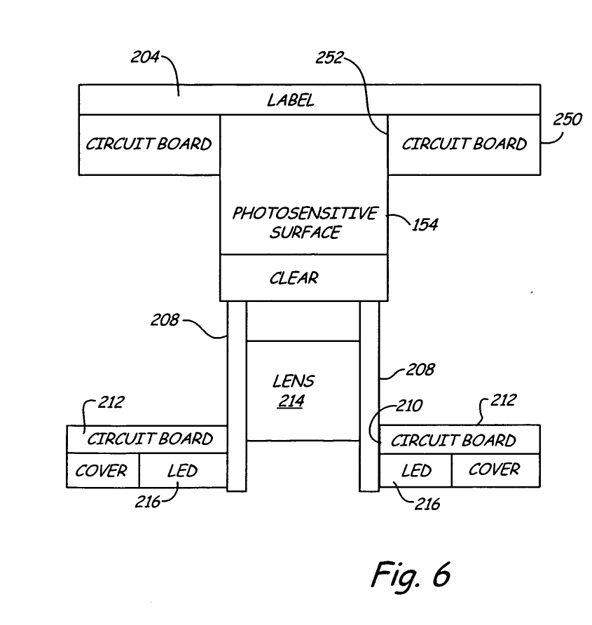

FIG. 6 is a diagrammatic view image acquisition system 154 coupled to circuit board 250 in accordance with an embodiment of the present invention. Some components of the system illustrated in FIG. 6 are similar to those illustrated with respect to FIG. 5, and like components are numbered similarly. Circuit board 250 has been adapted to have an aperture 252 sized to receive image acquisition system 154. As set forth above, image acquisition system 154 is preferably model KAC-0310 available from Kodak. This system is provided in a 48 pin ceramic leadless chip carrier (CLCC) having 12 attachment regions on each side. This arrangement allows image acquisition system 154 to be recessed into aperture 252 a distance of at least the thickness of circuit board 250. Since a typical circuit board thickness is approximately 1 millimeter, this results in a 1 millimeter thickness savings resulting in an overall thickness of approximately 7.5 millimeters for the configuration illustrated in FIG. 6.

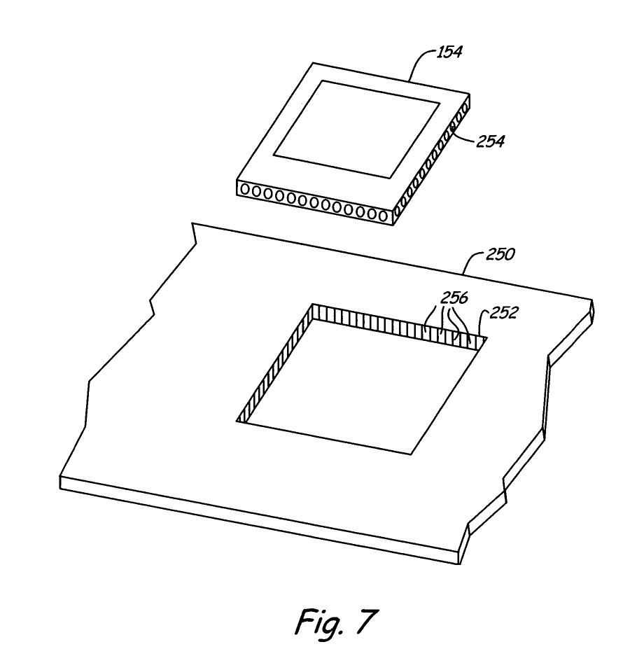

FIG. 7 is a perspective view illustrating image acquisition system 154 and circuit board 250 with aperture 252 therein. As shown in FIG. 7, image acquisition system 154 includes a number of connection points 254 disposed about its periphery. In order to engage points 254 of image acquisition system 154, circuit board 250 features a number of contact locations 256 that are arranged about the inner surface of aperture 252 in order to connection points 254 of system 154. Contact locations 256 can be created in any suitable manner including, but not limited to, forming an etched through-hole in circuit board 250 at each location of a contact location 256, then cutting through circuit board 250 to leave a portion of each etched through-hole behind in circuit board 250 thus forming a pad. Then, solder can be applied to join locations 256 to points 254 either by hand, or by machine.

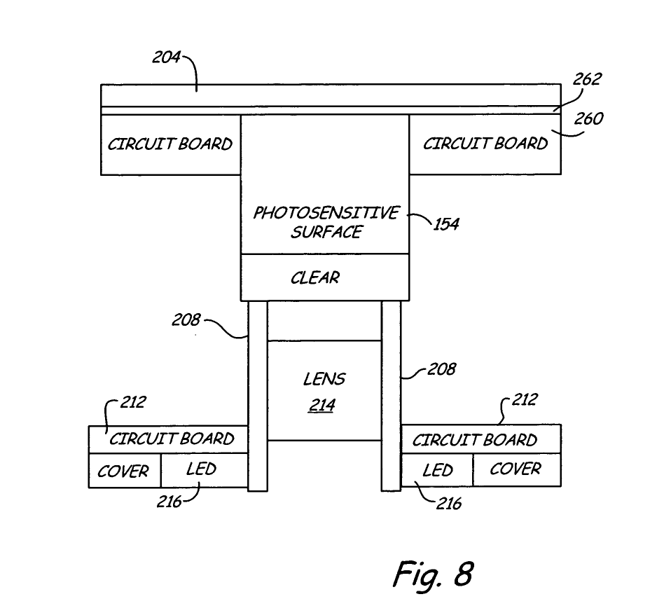

FIG. 8 is a diagrammatic view of an image acquisition system electrically coupled to a circuit board 260 in accordance with another embodiment of the present invention. Instead of electrical contact being made directly between image acquisition system 154 and circuit board 260, a flexible circuit 262 is provided to make electrical contact to both image acquisition system 154 and circuit board 260. A flexible circuit is generally a very thin electrical circuit formed by one or more conductive traces disposed between two layers of an insulating material. Flexible circuits are known to be as thin as 0.2 millimeters. In yet another embodiment, the CMOS chip itself within the image acquisition system can be removed and directly attached to the printed circuit board rather than housed in its conventional ceramic leadless chip carrier. However, in such embodiments, it is difficult to keep the optical surface of the imager clean. Moreover, it is believed that the assembly cost would be significantly increased and the overall reliability may be reduced.

In accordance with another embodiment of the present invention, a wireless substrate-like sensor is provided with improved safeguards against contaminating a semiconductor wafer processing chamber. It is extremely important that such sensors measure the physical properties while not contaminating the processing chamber. Moreover, such sensors must be dimensionally stable. Well known sensor materials and components may shed particles that could contaminate the wafer processing chamber. If a wireless substrate-like sensor is sealed to isolate potentially contaminating materials inside the sensor, a pressure differential may arise between the interior and exterior. If sufficiently extreme, the pressure differential could potentially deform the housing, or even cause a rupture. This is particularly so for a light-weight substrate-like sensor housing which may be mechanically weak due to the desire to minimize the total weight of the housing.

Wireless substrate-like sensors generally have an internal space and an external surface. Some of the sensor apparatus is contained within the internal space. The sensor housing includes a seal that prevents gas, particles or molecules from entering or leaving the internal space except through a vent that is specifically provided for that purpose. A filter is provided across the vent that allows the passage of gas, but prevents the passage of particles or molecules too large to fit through the filter. Preferably, the external surface of the sensor is constructed from or coated or deposited with chemically unreactive materials such as: nickel, polyethylene or polycarbonate. The shape and finish of the sensor housing is also preferably selected such that the sensor itself is easy to clean. External crevices and corners where particles may become trapped are also preferably minimized.

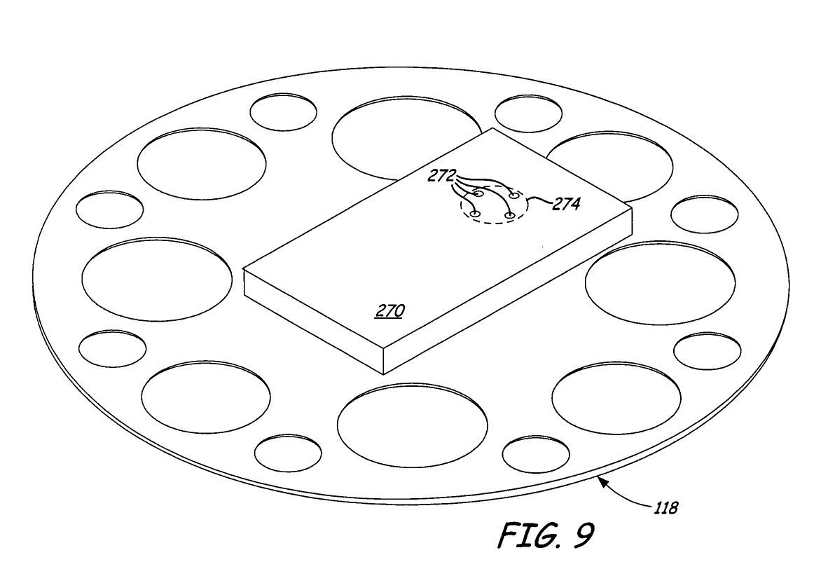

FIG. 9 is a perspective view of a sensor 118 having a sensor housing 270 thereon. Sensor housing 270 includes one or more perforations 272, which perforations 272 are the only passageways between the interior of housing 270 and the exterior. A suitable high molecular weight breather filter is preferably disposed within housing 270 proximate perforations 272. Filter 274 is illustrated in phantom in FIG. 9. The location of perforations 272 and the filter disposed proximate thereto can be provided at any suitable location on housing 270. Thus, they can be provided on the top surface as illustrated in FIG. 9, or on a side surface if desired. Perforations 272 protect the delicate filter 274 from mechanical damage and are relatively easy to fabricate. The use of perforations 272 and filter 274 prevents particles from exiting sensor housing 270 which would otherwise contaminate a semiconductor processing chamber. Perforations 272 allow the pressure within housing 270 to equalize with the pressure of the chamber thus preventing deformation of housing 270, or worse.

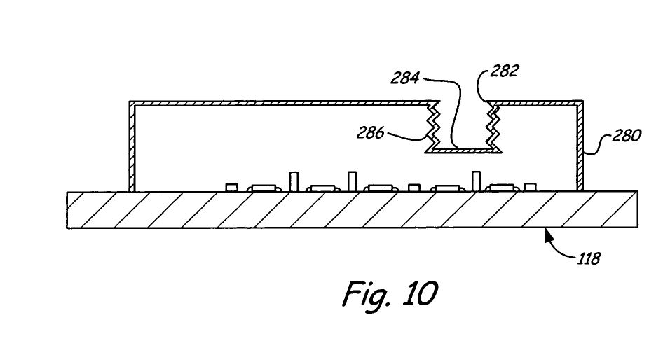

FIG. 10 is a cross sectional view of a wireless substrate-like sensor 118 with a contamination resistant sensor housing 280 in accordance with another embodiment of the present invention. Sensor housing 280 is hermetically sealed. An aperture 282 is completely sealed with a deformable pressure equalization member 284. Member 284 is preferably constructed from a resilient material such that it will return to its original shape when a given pressure is removed. Preferably, member 284 includes bellows 286, but may take the form of any suitable shape that is able to deform in response to a pressure differential. Thus, member 284 may be a balloon, a bladder, or any other suitable configuration. In this embodiment, pressure inside sensor housing 280 is equalized with the chamber pressure by deformation of member 284 without allowing deformation of housing 280.

Although the present invention has been described with reference to preferred embodiments, workers skilled in the art will recognize that changes may be made in form and detail without departing from the spirit and scope of the invention.

1. A low-profile substrate-like sensor for use in semiconductor processing tool, the sensor comprising:
a housing having a support element and sensing electronics disposed thereon; and
wherein the sensing electronics includes a rigid interconnect having a recessed portion, and a sensing element disposed in the recessed portion and being electrically coupled to the sensing electronics.

2. The sensor of claim 1, wherein the sensing element is an image sensor.

3. The sensor of claim 1, wherein the recessed portion is a hole through the rigid interconnect.

4. The sensor of claim 1, wherein the recessed portion is a cutout.

5. The sensor of claim 4, wherein the cutout is U-shaped.

6. The sensor of claim 4, wherein the cutout is rectangular.

7. The sensor of claim 1, wherein the sensing element is carried within a ceramic leadless chip carrier.

8. The sensor of claim 1, wherein the recessed portion comprises a flexible interconnect.

9. A low-profile substrate-like sensor for use in semiconductor processing tool, the sensor comprising:
a housing having a support platform and sensing electronics disposed thereon; and
wherein the sensing electronics includes a circuit having an image acquisition chip disposed thereon and being electrically coupled to the sensing electronics.

10. The sensor of claim 9, wherein the image acquisition chip is coupled to the sensing electronics by flip chip techniques.

11. The sensor of claim 9, wherein the image acquisition chip is coupled to the sensing electronics by die attachment and wire bonding techniques.
